(19) United States
(12) Patent Application Publication
(10) Pub. No.: US 2024/0079272 A1
(43) Pub. Date: Mar. 7, 2024

(54) METHOD OF MANUFACTURING SEMICONDUCTOR CHIP INCLUDING FORMING DICING GROOVES AND SEMICONDUCTOR DEVICE

(71) Applicant: SK hynix Inc, Gyeonggi-do (KR)

(72) Inventors: Byung Cheol LEE, Gyeonggi-do (KR); Jong Su KIM, Gyeonggi-do (KR)

(21) Appl. No.: 18/087,811

(22) Filed: Dec. 23, 2022

(30) Foreign Application Priority Data
Sep. 5, 2022 (KR) 10-2022-0112433

(51) Int. Cl. H01L 21/78

(52) U.S. Cl. CPC H01L 21/78; H01L 21/268

(57) ABSTRACT

A method of manufacturing a semiconductor chip and a semiconductor device. The method of manufacturing the semiconductor chip includes a process of dicing a substrate. The substrate includes an active layer and an organic layer on the semiconductor base. Dicing grooves that are extended to face each other along first dicing lines from points, at which the first dicing lines and second dicing lines along which the substrate is to be diced intersect, are formed by recessing some parts of the active layer. Modified patterns are formed within the semiconductor base. The substrate is diced into semiconductor chips by propagating cracks into the substrate from the modified patterns.

### CROSS-REFERENCE TO RELATED APPLICATION

The present application claims priority under 35 U.S.C. § 119(a) to Korean application number No. 10-2022-0112433, filed in the Korean Intellectual Property Office on Sep. 5, 2022, the entire disclosure of which is incorporated herein by reference.

### BACKGROUND

The present disclosure relates to a semiconductor technology and, particularly, to a method of manufacturing a semiconductor chip including forming dicing grooves and a semiconductor device.

Semiconductor devices or integrated circuits are integrated on a substrate, such as a wafer. A plurality of semiconductor chips may be separated from the substrate on which the semiconductor devices or the integrated circuits have been integrated by dicing the substrate. The semiconductor chips may include the semiconductor devices or the integrated circuits. In a process of dicing the substrate, in order to reduce a substrate consumption part that is consumed for the dicing, there are presented attempts to replace a blade dicing process with a dicing process using a laser.

In the dicing process using a laser, a non-dicing failure in which the semiconductor chips are not diced may occur. As the non-dicing failure occurs, dicing power at a corner portion of the semiconductor chip may be reduced. As the dicing power at the corner portion of the semiconductor chip is reduced, a layer delamination phenomenon may occur at the corner portion of the semiconductor chip, or a dicing failure, such as a phenomenon in which some part of the semiconductor chip is chipped off in an unwanted direction, may occur. In order to reduce such a failure, various dicing methods are being attempted.

### SUMMARY

One embodiment of the present disclosure provides a semiconductor device including forming a substrate that includes an active layer and an organic layer on a semiconductor base, forming dicing grooves that are extended to face each other along first dicing lines from points at which the first dicing lines and second dicing lines along which the substrate is to be diced intersect by recessing some parts of the active layer, forming modified patterns within the semiconductor base, and dicing the substrate into semiconductor chips by propagating cracks into the substrate from the modified patterns.

Another embodiment of the present disclosure provides a method of manufacturing a semiconductor chip, including forming a substrate that includes an active layer and an organic layer on a semiconductor base and in which first and second scribe lane regions intersect to partition chip regions, forming dicing grooves that are extended to face each other in a direction in which the first scribe lane regions are extended from points at which the first and second scribe lane regions intersect by recessing some parts of the active layer, forming modified patterns within the semiconductor base, and dicing the substrate into semiconductor chips by propagating cracks into the substrate from the modified patterns.

Another embodiment of the present disclosure provides a semiconductor device including a substrate including an active layer and an organic layer on a semiconductor base, wherein dicing grooves that are extended to face each other along first dicing lines from points at which the first dicing lines and second dicing lines along which the substrate is to be diced intersect are formed in the active layer. The semiconductor device may further include modified patterns that are aligned in a line along the first and second dicing lines within the semiconductor base and some of the modified patterns overlap the dicing grooves.

### BRIEF DESCRIPTION OF THE DRAWINGS

FIGS. 1 to 17 are schematic diagrams illustrating a semiconductor chip and a method of manufacturing the semiconductor chip according to various embodiments of the present disclosure.

FIG. 18 is a schematic diagram illustrating a semiconductor chip and a method of manufacturing the semiconductor chip according to one embodiment of the present disclosure,

FIGS. 19 and 20 are process flowcharts illustrating methods of manufacturing a semiconductor chip according to various embodiments of the present disclosure.

FIG. 21 is a block diagram illustrating an electronic system using a memory card including a semiconductor chip according to one embodiment of the present disclosure.

FIG. 22 is a block diagram illustrating an electronic system including a semiconductor chip according to one embodiment of the present disclosure.

### DETAILED DESCRIPTION

Terms that are used in the description of examples of this application may in some of the examples be terms selected by taking into consideration functions in the disclosed embodiments, and the meanings of the terms may be different depending on a user, an operator's intention or practice in the technical field. The meaning of a term as used herein either follows the definition of the term if the term has been specifically defined in this specification or may follow a meaning which may be commonly recognized by those skilled in the art if the term has not been specifically defined, or may follow the plain and ordinary meaning of the term.

In the description of examples of this application, terms, such as a “first”, a ‘second”, a “side”, a “top”, and a “bottom or lower”, are used to distinguish between members and are not used to limit the members themselves or to mean a specific order.

A semiconductor substrate may denote a semiconductor wafer on which electronic parts and elements are integrated. Integrated circuits may be integrated on the semiconductor substrate. The semiconductor substrate may be diced into a plurality of semiconductor chips or a plurality of semiconductor dies.

The semiconductor chip may be a memory chip on which memory devices, such as for example DRAM, SRAM, NAND flash memory, NOR flash memory, MRAM, ReRAM, FeRAM, or PcRAM, have been integrated. The semiconductor chip may denote a logic die or an ASIC chip, an application processor (AP), a graphic processing unit (GPU), a central processing unit (CPU), or a system on chip (SOC) in which logic circuits have been integrated on a semiconductor substrate.

The semiconductor chip may be a component that constitutes a semiconductor package or a semiconductor product. The semiconductor chip may be applied to information communication devices such as a mobile terminal, bio or health care-related electronic devices, and electronic devices wearable by human beings. The semiconductor chip may be applied to devices for the Internet of Things.

In the specification, the same reference numerals may denote the same components. Accordingly, the same reference numerals or similar reference numerals may be described with reference to other drawings although they are not mentioned or described in corresponding drawings. Furthermore, although reference numerals are not shown, they may be described with reference to other drawings.

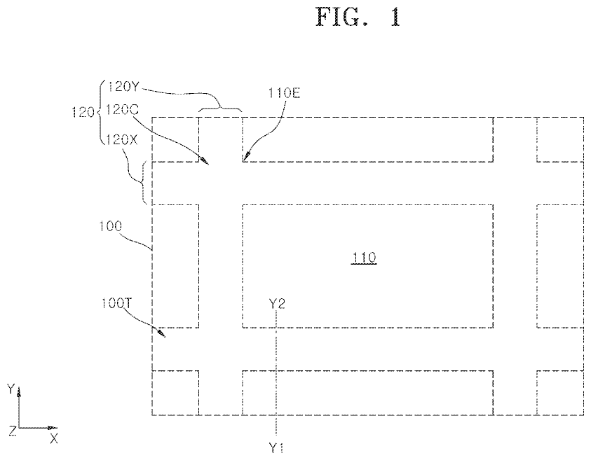

FIGS. 1 to 17 are schematic diagrams illustrating a semiconductor chip and a method of manufacturing the semiconductor chip according to various embodiments of the present disclosure. FIG. 1 is a schematic plan view illustrating a substrate 100 on which a method of manufacturing a semiconductor chip according to an embodiment is performed, FIG. 1 may schematically illustrate a shape in which regions 110 and 120 of the substrate 100 have been disposed on an X-Y plane.

Referring to FIG. 1, a method of manufacturing a semiconductor chip according to one embodiment of the present disclosure may include process steps of separating the substrate 100 into individual semiconductor chips. The substrate 100 may have a wafer shape. The substrate 100 may be a device substrate on which memory devices, semiconductor devices, or integrated circuits have been integrated. The substrate 100 may include chip regions 110 and a scribe lane region 120. The scribe lane region 120 may be a region that is disposed between the chip region 110 and another chip region 110 that is adjacent to the chip region 110. The scribe lane region 120 may be a region that partitions the chip regions 10 by surrounding the chip regions 110.

The chip region 110 may be a region on which semiconductor devices, integrated circuits, or memory devices are integrated or disposed. The memory devices may be volatile memory devices, such as for example dynamic random access memory (DRAM). The memory devices may be nonvolatile memory devices, such as for example flash memory. The chip regions 110 may be regions to be separated into individual semiconductor chips by a dicing process. The chip region 110 may be a region in which pattern density is relatively high. The scribe lane region 120 may be a region in which pattern density is relatively low as compared to the density of the patterns in the chip region 110.

The substrate 100 may include first scribe lane regions 120X and second scribe lane regions 120Y that intersect. The first scribe lane regions 120X and the second scribe lane regions 120Y may intersect at cross points 120C or otherwise referred to as cross regions. The cross points 120C at which the first scribe lane regions 120X and the second scribe lane regions 120Y intersect may be regions in which corners 110E of the chip regions 110 face each other. The chip regions 110 may be disposed so that four corners 110E of four chip regions 110 that are adjacent to one another face one another at the cross point 120C.

The first scribe lane region 120X may be extended in a first direction which may be an X axis direction on the X-Y plane. The second scribe lane region 120Y may be extended in a second direction which may be a Y axis direction on the X-Y plane. The second direction may be a direction that is intersected with the first direction. When viewed from the X-Y plane, the chip region 110 may have a square or oblong shape in which four corners neighbor four cross points 120C, respectively.

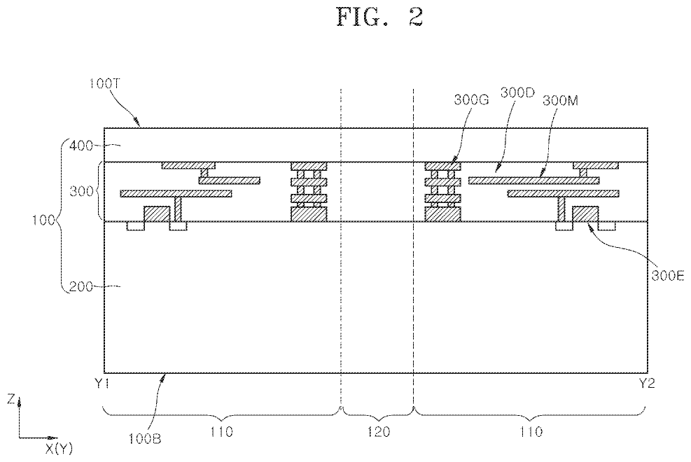

FIG. 2 is a schematic cross-sectional view illustrating a cross-sectional shape of the substrate 100 in FIG. 1. FIG. 2 may illustrate a cross-sectional shape according to the cutting-plane line Y1-Y2 shown in FIG. 1.

Referring to FIG. 2, the substrate 100 may include a semiconductor base 200, an active layer 300, and an organic layer 400. The semiconductor base 200 may denote a semiconductor substrate or semiconductor wafer that is constituted with a semiconductor material. The semiconductor base 200 may include a semiconductor material, such as for example silicon (Si) or germanium (Ge), The semiconductor base 200 may include a compound semiconductor material, such as for example silicon carbide (SiC), gallium arsenide (GaAs), indium arsenide (InAs), or indium phosphorous (InP).

Electronic elements 300E that constitute a semiconductor device, a memory device, or an integrated circuit may be integrated on the semiconductor base 200. The electronic elements 300E may include transistor structures. The electronic elements 300E may be disposed in the chip region 110. The electronic elements 300E may constitute volatile memory devices or may constitute nonvolatile memory devices.

The active layer 300 may include a plurality of conductive patterns 300M and a dielectric layer 300D. The dielectric layer 300D may include a structure in which a plurality of interlayer dielectric layers has been stacked. The dielectric layer 300D may include an insulating material, such as for example silicon oxide (SiO₂). The dielectric layer 300D may further include an insulating material, such as for example silicon nitride (Si₃N₄). The active layer 300 may include various types of material layers that constitute integrated circuits or memory devices. The active layer 300 may be a device layer including elements that constitute integrated circuits or memory devices.

The conductive patterns 300M may include wiring layers that constitute a part of a semiconductor device, a memory device, or an integrated circuit. The dielectric layer 300D may include insulating layers that insulate the wiring layers. The dielectric layer 300D may be a layer that electrically isolates the plurality of conductive patterns 300M from each other. The conductive patterns 300M may include a gate layer, word lines, bit lines, or multi-layer metal lines that constitute a transistor structure or a memory device.

Some of the conductive patterns 300M may be also disposed in the scribe lane region 120 in addition to the chip region 110. The conductive patterns 300M may be formed in the chip region 110 with relatively high pattern density, and may be formed in the scribe lane region 120 with relatively low pattern density as compared to the density of the patterns in chip region 110. Some of the conductive patterns 300M may be formed in the scribe lane region 120 as test patterns or as process monitoring patterns. Some of the conductive patterns 300M may be disposed to constitute a chip guard 300G in a part of the chip region 110, which is disposed at the boundary of the scribe lane region 120 and the chip region 110. The conductive pattern 300M and the chip guards 300G may include a metal material, such as aluminum (Al) or copper (Cu).

The organic layer 400 may be a layer that covers and protects the active layer 300. The organic layer 400 may include a polymer layer. The organic layer 400 may include poly(imide-isoindoloquinazolinedione) (PIQ). The top of the organic layer 400 may provide a first surface 100T of the substrate 100. The substrate 100 may have a second surface 100B that is opposite to the first surface 100T, The second surface 100B of the substrate 100 may be the backside of the semiconductor base 200 that is opposite to the active layer 300.

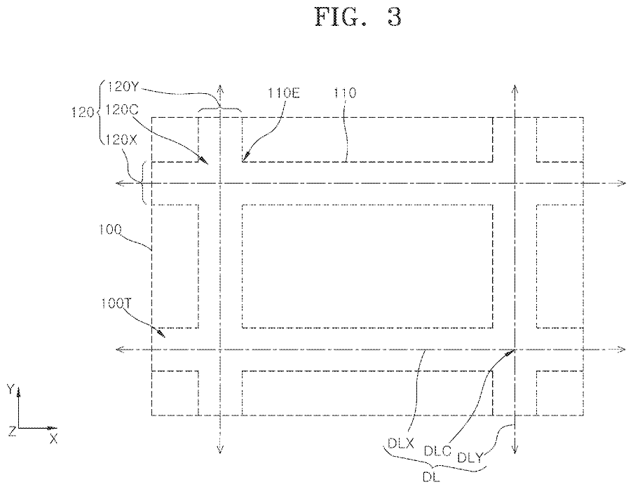

FIG. 3 is a schematic plane view illustrating dicing lines DL in a method of manufacturing a semiconductor chip according to one embodiment.

Referring to FIG. 3, the scribe lane region 120 of the substrate 100 may be a region in which a dicing process of dicing the substrate 100 into individual semiconductor chips is performed. The dicing lines DL that dice the substrate 100 may be set in the direction in which the scribe lane regions 120 are extended. The dicing lines DL may indicate a location to be diced from the first surface 100T of the substrate 100 to the second surface (100B in FIG. 2) that is opposite to the first surface 100T.

A first dicing line DLX may be set as a virtual line that is extended along the first scribe lane region 120X. The first dicing line DLX may be set to indicate a first dicing direction as the X axis direction and a first dicing location. A second dicing line DLY may be set as a virtual line that is extended along the second scribe lane region 120Y. The second dicing line DLY may be set to indicate a second dicing direction as the Y axis direction and a second dicing location. The first dicing lines DLX and the second dicing lines DLY may intersect at cross points DLC. The cross points DLC of the first dicing lines DLX and the second dicing lines DLY may be disposed within the cross points 120C at which the first and second scribe lane regions 120X and 120Y intersect.

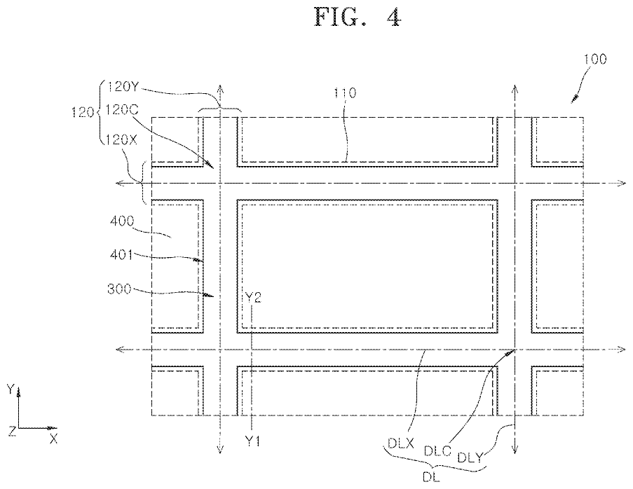

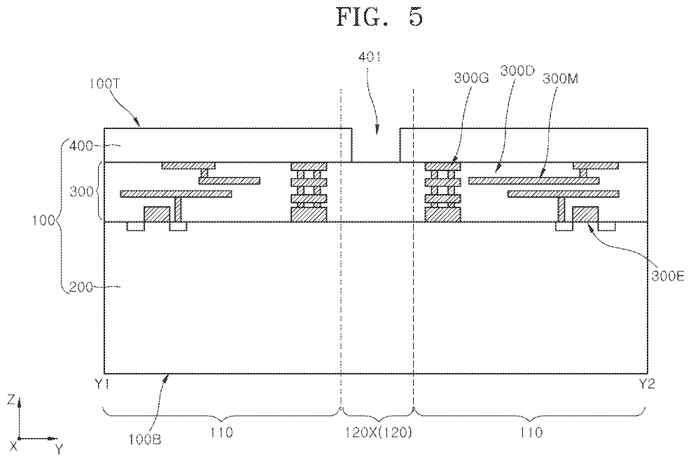

FIG. 4 is a schematic plane view illustrating a step of forming an opening portion 401 of the organic layer 400 in a method of manufacturing a semiconductor chip according to another embodiment. FIG. 5 is a schematic cross-sectional view illustrating a cross-sectional shape along the cutting-plane line Y1-Y2 shown in FIG. 4.

Referring to FIGS. 4 and 5, the opening portion 401 that exposes some part of the active layer 300 under the organic layer 400 may be formed by selectively removing some part of the organic layer 400. The opening portion 401 may be formed in a shape that is extended along the scribe lane region 120. The opening portion 401 may be formed in a shape that is extended along the first and second scribe lane regions 120X and 120Y. The opening portion 401 may be formed in a shape that surrounds the chip region 110. The opening portion 401 may be formed in a shape that is extended along the first and second dicing lines DLX and DLY.

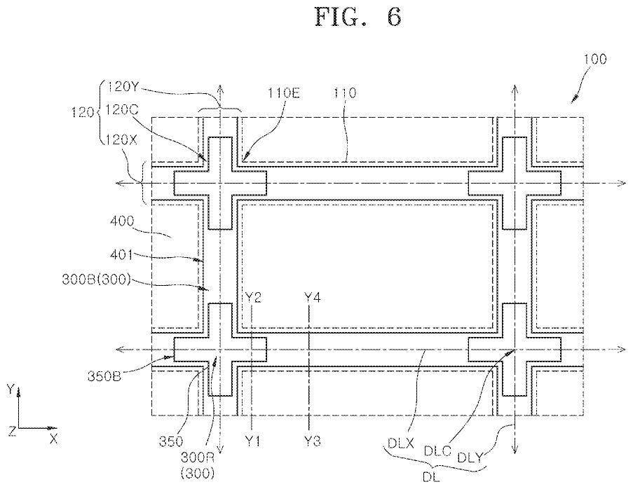

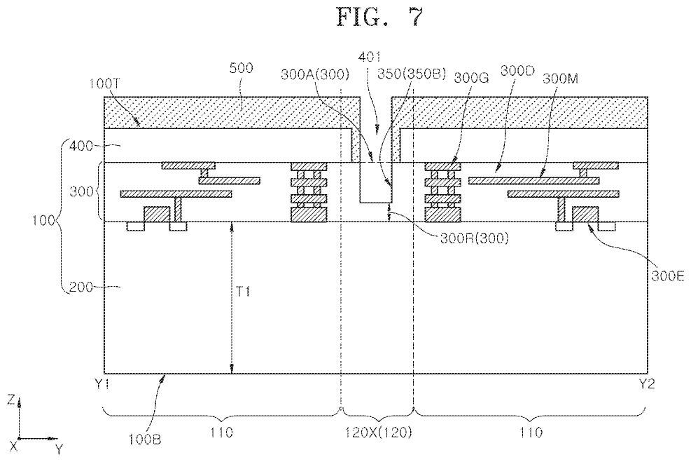

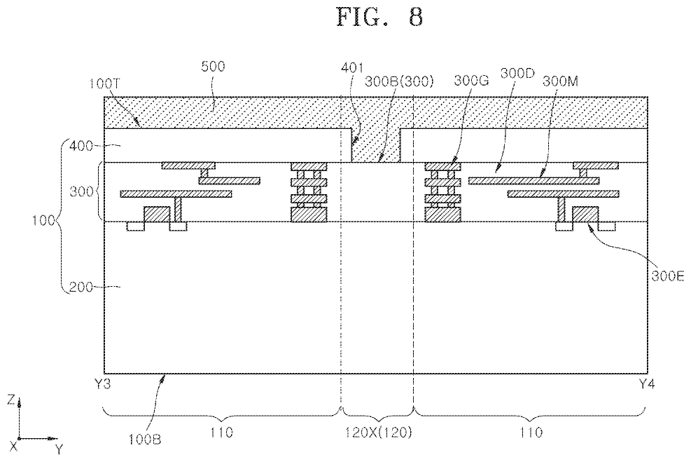

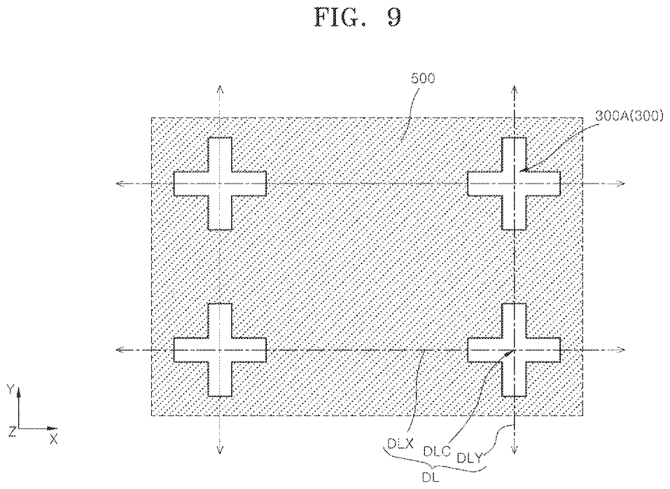

FIG. 6 is a schematic plane view illustrating a step of forming dicing grooves 350 in the active layer 300 in a method of manufacturing a semiconductor chip according to still another embodiment. FIG. 7 is a schematic cross-sectional view illustrating a cross-sectional shape along the cutting-plane line Y1-Y2 shown in FIG. 6. FIG. 8 is a schematic cross-sectional view illustrating a cross-sectional shape along a cutting-plane line Y3-Y4 shown in FIG. 6. FIG. 9 is a schematic plane view illustrating a plan view shape of a mask pattern 500 in FIGS. 7 and 8.

Referring to FIG. 6, the dicing grooves 350 may be formed in the active layer 300 of the substrate 100. The dicing grooves 350 may have plan view shapes that are extended from the cross points DLC at which the first and second dicing lines DLX and DLY (along which the substrate 100 will be diced) intersect in a way to face each other along the first dicing lines DLX. The dicing grooves 350 may have plan view shapes that are further extended from the cross points DLC along the second dicing lines DLY. The dicing grooves 350 may be formed in cross-shaped plan view shapes in which branches 350B extended from the cross points DLC, respectively, along the first and second dicing lines DLX and DLY intersect. When viewed from a plane, the dicing grooves 350 may be formed to be isolated from each other along the first dicing lines DLX or the second dicing lines DLY.

The dicing grooves 350 may have plan view shapes that are extended from the cross points 120C (at which the first and second scribe lane regions 120X and 120Y of the substrate 100 intersect) in a way to face each other in the direction in which the first scribe lane regions 120X are extended. The dicing grooves 350 may have plan view shapes that are further extended from the cross points 120C along the second scribe lane regions 120Y. The dicing grooves 350 may be formed in cross-shaped plan view shapes in which the branches 3503 (that are extended from the cross points 120C along the first and second scribe lane regions 120X and 120Y) intersect when viewed on a plane. When viewed on the plane, the dicing grooves 350 may be formed to be isolated from each other along the first scribe lane regions 120X or the second scribe lane regions 120Y. Referring to FIGS. 6 and 7, the dicing grooves 350 may be formed so that remaining portions (300R in FIG. 7) of the active layer 300 remain at the bottoms of the dicing grooves 350 at a certain depth, leaving a thickness of the active layer unremoved. The dicing grooves 350 having a certain depth may be formed in the active layer 300 by selectively recessing and removing some parts 300A of the active layer 300 of the substrate 100.

Referring to FIGS. 6, 7, and 8, some parts 300E of the active layer 300 that overlap in the scribe lane region 120 may remain without being recessed between the dicing groove 350 and another dicing groove 350 adjacent to the dicing groove 350. The opening portion 401 of the organic layer 400 may be formed in a shape that exposes the dicing grooves 350, and may also be formed on the active layer 300 in a way to expose some parts 3003 of the active layer 300 that are disposed between the dicing grooves 350.

Referring to FIGS. 7 and 9, the dicing grooves 350 may be formed by a selective etch process using the mask pattern 500 as an etch mask. The mask pattern 500 may be formed to include a photoresist pattern. The mask pattern 500 that exposes selected parts 300A of the active layer 300 may be formed by coating a photoresist layer on the organic layer 400 and exposing and developing the photoresist layer. The mask pattern 500 may be formed to cover the organic layer 400 and to cover other parts 300B of the active layer 300, which will be disposed between the dicing grooves 350 as shown in FIG. 8, while exposing the selected parts 300A of the active layer 300 in which the dicing grooves 350 will be formed as shown in FIG. 7. The dicing groove 350 may be formed to have a sidewall that has a stair-shaped step.

Referring back to FIG. 7, the selected parts 300A of the active layer 300 that are exposed to the mask pattern 500 may be recessed by etching the selected parts 300A of the active layer 300. As the selected parts 300A of the active layer 300 are recessed, the dicing grooves 350 may be formed in the active layer 300. The selected parts 300A of the active layer 300 that are removed by forming the recess may be parts of the active layer 300 that include the dielectric layer 300D. The conductive patterns 300M may be excluded and may not be disposed in the selected parts 300A of the active layer 300 that are removed by forming the recess.

A recess process or etch process of forming the dicing grooves 350 may be performed so that the remaining portions 300R of the active layer 300 remain between the bottoms of the dicing grooves 350 and the semiconductor base 200. Since a part of the semiconductor base 200 is not exposed to the dicing grooves 350 by the remaining portions 300R of the active layer 300, the semiconductor base 200 can be protected against any external environment by not being exposed to the external environment. The remaining portions 300R of the active layer 300 may have a thickness smaller than a thickness T1 of the semiconductor base 200 (see FIG. 7). A process of recessing the dicing grooves 350 may be performed so that the remaining portions 300R of the active layer 300 have a thickness that is 20% or less of the thickness T1 of the semiconductor base 200, A process of recessing the dicing grooves 350 may be performed so that the remaining portions 300R of the active layer 300 have a thickness of 2 micrometers (μm) or less. After the dicing grooves 350 are formed, the mask pattern 500 may be removed from the substrate 100.

Referring back to FIG. 6, the dicing grooves 350 may be formed to be disposed adjacent to the respective corners 110E of the chip region 110 to be diced into semiconductor chips. The dicing grooves 350 may be limited to be disposed at only some parts of the scribe lane region 120 that are adjacent to the corners 110E of the chip region 110. The dicing grooves 350 may be formed to be disposed only in limited regions in a way to be isolated from one another without being connected. As described above, since the dicing grooves 350 are limited to be disposed in outer regions of the corners 110E of the chip region 110, a process burden of a recess process of forming the dicing grooves 350 can be reduced compared to a case in which the dicing grooves 350 are formed to be extended across the entire region of the scribe lane region 120.

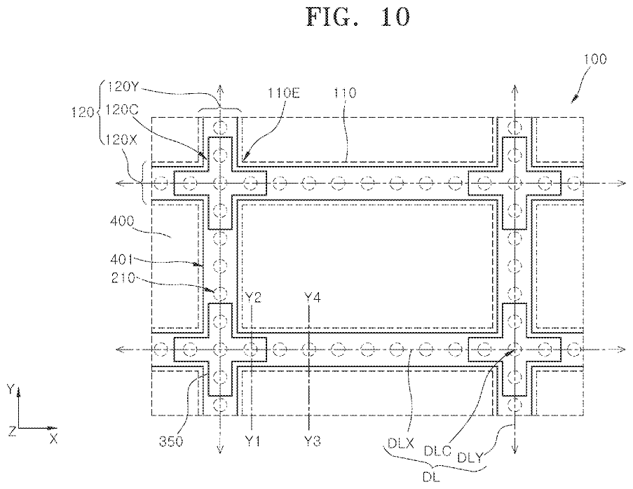

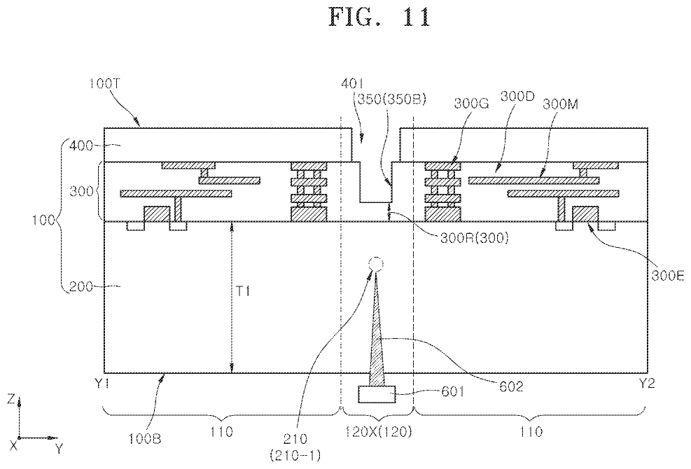

FIG. 10 is a schematic plan view illustrating a step of forming modified patterns 210 in a method of manufacturing a semiconductor chip according to yet another embodiment. FIG. 11 is a schematic cross-sectional view illustrating a cross-sectional shape along the cutting-plane line Y1-Y2 shown in FIG. 10. FIG. 12 is a schematic cross-sectional view illustrating a cross-sectional shape along the cutting-plane line Y3-Y4 shown in FIG. 10.

Referring to FIGS. 10 and 11, the modified patterns 210 for dicing may be formed within the substrate 100, The modified patterns 210 may be formed by performing a dicing process using laser light 602, for example, by performing a stealth dicing process (as detailed below). The modified patterns 210 may be formed in some parts of the semiconductor base 200 in the scribe lane region 120. The modified patterns 210 may be formed within the substrate 100 in the stealth process by sequentially radiating the laser light 602 while sequentially focusing on locations at which the modified patterns 210 within the substrate 100 will be formed by using a laser apparatus 601.

The modified patterns 210 may be formed within the semiconductor base 200 in the stealth process by repeating the operation of radiating the laser light 602 while focusing on the locations at which the modified patterns 210 within the substrate 100 will be formed. The radiation of the laser light 602 for forming the modified patterns 210 in the stealth process may be sequentially performed along the first dicing lines DLX. The modified patterns 210 may be formed to be aligned in a line along the first dicing line DLX. The radiation of the laser 602 for forming the modified patterns 210 may be sequentially performed along the first scribe lane regions 120X. The modified patterns 210 may be formed to be aligned in a line along the first scribe lane regions 120X.

Furthermore, the modified patterns 210 may be formed in the stealth process to be aligned in a line along the second dicing lines DLY. The radiation of the laser 602 for forming the modified patterns 210 in the stealth process may be sequentially performed along the second dicing lines DLY. The radiation of the laser light 602 for forming the modified patterns 210 in the stealth process may be sequentially performed along the second scribe lane regions 120Y. The modified patterns 210 may be formed to be aligned in a line along the second scribe lane regions 120Y. As presented in FIG. 11, some portion 210-1 of the modified patterns 210 may be formed to overlap the dicing grooves 350. As presented in FIG. 12, other portions 210-2 of the modified patterns 210 may overlap some part 300B of the active layer 300, which is disposed between the dicing grooves 350. As described above, the array of the modified patterns 210 or a layer of the modified patterns 210 may be formed within the substrate 100 or within the semiconductor base 200 by the radiation of the laser. Since such a process may be performed by the stealth dicing process, the layer of the modified patterns 210 may also be referred to herein as a stealth dicing layer forming stealth dicing patterns.

The modified patterns 210 may have physical properties different from those of the semiconductor base 200. As some parts of the semiconductor base 200 are modified by the radiation of the laser 602, the modified patterns 210 may be formed within the semiconductor base 200. If the semiconductor base 200 is constituted to include single crystal silicon, the modified patterns 210 may include amorphous silicon or polycrystalline silicon. As single crystal silicon is modified into amorphous silicon or polycrystalline silicon, stress according to this modification in the crystal structure may be induced around the modified patterns 210. The modified patterns 210 may cause stress nearby. The modified patterns 210 may act as an element that generates cracks due to such stress.

The laser light 602 may be radiated so that the plurality of modified patterns 210 are formed at spaced apart intervals along the scribe lane region 120. The modified patterns 210 may be formed in a way to be regularly repeated at the spaced apart intervals within the semiconductor base 200 in the scribe lane region 120. For example, the modified patterns 210 may be formed to be spaced apart from each other at an interval of several micrometers (μm) to several tens of micrometers (μm). The modified patterns 210 may be spaced apart from each other at an interval of approximately 2 μm to 10 μm. The modified pattern 210 may have a size of several micrometers. The modified pattern 210 may be formed to have an ellipsoidal shape that is long in the thickness direction of the semiconductor base 200.

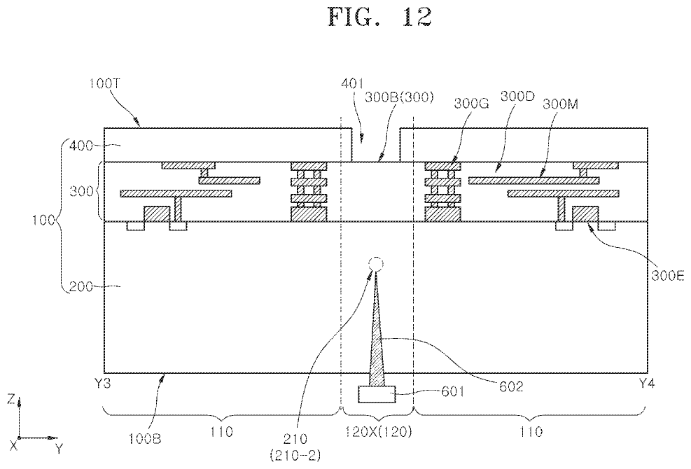

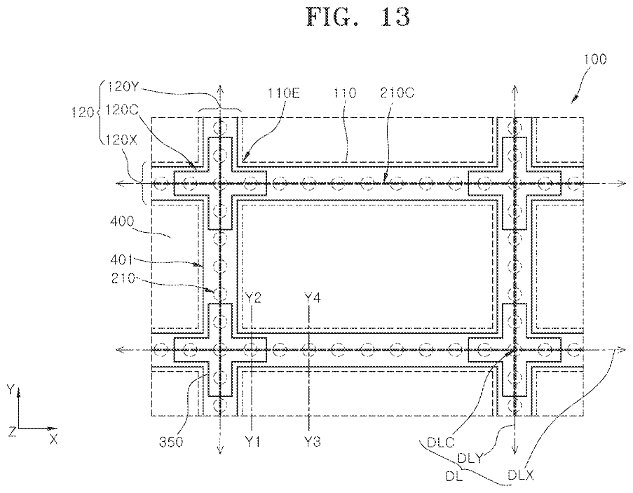

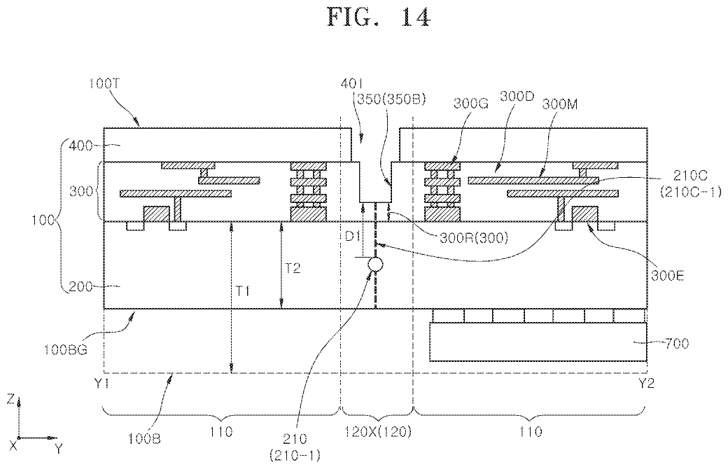

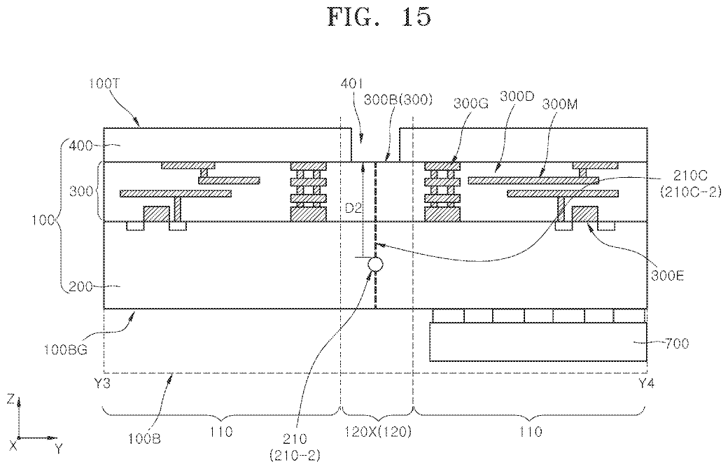

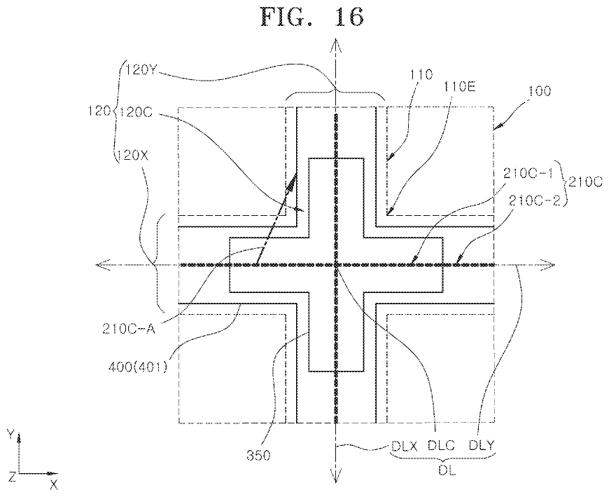

FIG. 13 is a schematic plan view illustrating a step of dicing the substrate 100 in a method of manufacturing a semiconductor chip according to still yet another embodiment. FIG. 14 is a schematic cross-sectional view illustrating a cross-sectional shape along the cutting-plane line Y1-Y2 shown in FIG. 13. FIG. 15 is a schematic cross-sectional view illustrating a cross-sectional shape along the cutting-plane line Y3-Y4 shown in FIG. 13. FIG. 16 is a schematic plan view enlarging and illustrating a part of the dicing groove 350 of the substrate 100 shown in FIG. 13. FIG. 17 is a schematic plan view illustrating that the substrate 100 has been diced into the semiconductor chips 110C in FIG. 13.

Referring to FIG. 13, cracks 210C may occur from the modified patterns 210, The cracks 210C that have occurred may grow and propagate into the substrate 100. As the cracks 210C are propagated, the cracks 210C may grow so that crack sections including the cracks 210C dice the substrate 100. Since stress has already occurred around the modified patterns 210, when an external force is applied to the substrate 100, the cracks 210C may occur around the modified patterns 210 by the stress and the external force. As the cracks 210C grow, the cracks 210C may be propagated into the substrate 100 or the semiconductor base 200.

In one embodiment, the modified patterns 210 are aligned along the dicing lines DL. Accordingly, as the cracks 210C are propagated, the crack sections may be induced, grown, or propagated along the dicing lines DL. The crack sections may be formed as the cracks 210C are gathered or interconnected. The crack sections may induce dicing sections that dice the substrate 100 or may act as the dicing sections. The modified patterns 210 are aligned in the direction in which the first dicing lines DLX or the first scribe lane regions 120X are extended. Accordingly, the crack sections along the first dicing lines DLX may be propagated or the crack sections may be propagated in the direction in which the first scribe lane regions 120X are extended. In line with such propagation, other modified patterns 210 are aligned along the second dicing lines DLY or the second scribe lane regions 120Y. Accordingly, other crack sections along the second dicing lines DLY or the second scribe lane regions 120Y may be propagated simultaneously with the crack sections along the first dicing lines DLX.

Referring to FIGS. 14 and 15 along with FIG. 13, a step of dicing the substrate 100 may include a step of back grinding the substrate 100. A step of grinding the second surface 100E that is opposite to the first surface 100T of the substrate 100 may be performed. In the process of back grinding the second surface 100B of the substrate 100, an external force may be applied to the substrate 100. The substrate 100 may be mounted on a substrate support part so that the first surface 1001 of the substrate 100 faces the substrate support part of the grinding apparatus. A grinder 700 (as shown in FIG. 14) may be introduced into the second surface 1003 of the substrate 100. The substrate 100 may be back ground by driving the grinder 700. A protection film that covers the first surface 100T of the substrate 100 may be introduced. By the back grilling, the semiconductor base 200 of the substrate 100 may be processed to have a thickness T2 that is smaller than the initial thickness T1. The substrate 100 may be processed to have a third surface 100BG (as shown in FIG. 14) as the substrate 100 is back ground by the grinder 700. As the substrate 100 is back ground as described above, the substrate 100 may have a thickness that is smaller than an initial thickness. The back grinding process may be performed as a process of thinly processing the thickness of the substrate 100. As presented in FIG. 14, a process of back grinding the semiconductor base 200 may be performed so that the thickness of the remaining portion 300R of the active layer 300 in which the dicing groove 350 has been formed is 20% or less of the thickness T2 after the back grinding of the semiconductor base 200. The dicing groove 350 may have a depth of 100 nanometers (nm) or more. The remaining portion 300R of the active layer 300 may have a thickness of 2 micrometers (μm) or less. The semiconductor base 200 may have the thickness T2 of about 10 micrometers after the back grinding.

Referring to FIGS. 14 and 15, the cracks 210C may be propagated so that the cracks 210C pass in the thickness direction of the semiconductor base 200 of the substrate 100, and may be further propagated so that the cracks 210C pass through the active layer 300 on the semiconductor base 200 in the thickness direction of the active layer 300. The crack sections may act as the dicing sections that dice the substrate 100 by such propagation of the cracks 210C.

As presented in FIG. 14, a first crack 210C-1 that has been propagated from a first modified pattern 210-1 that is disposed to overlap the dicing groove 350 formed in the active layer 300 may be propagated so that one end of the first crack 210C-1 is exposed at the bottoms of the dicing groove 350. As presented in FIG. 15, a second crack 210C-2 that has been propagated from a second modified pattern 210-2 that does not overlap the dicing groove 350 may be propagated so that one end of the second crack 210C-2 is exposed on a surface of some parts 3003 of the active layer 300. As the dicing groove 350 has been formed, a distance D1 in which the first crack 210C-1 passes through the substrate 100 may be shorter than a distance D2 in which the second crack 210C-2 passes through the substrate 100. Accordingly, while the second crack 210C-2 is propagated while passing through some parts 300B of the active layer 300 of the substrate 100, the second crack 210C-2 may substantially fully pass through the remaining portion 300R of the active layer 300 of the substrate 100, and may substantially fully dice the substrate 100.

Referring to FIGS. 13 and 16, the first and second dicing lines DLX and DLY may intersect and the first and second scribe lane regions 120X and 120Y may intersect in a region outside the corner 110E of the chip region 110 or a region adjacent to the corner 110E of the chip region 110. Since the cracks 210C are propagated along the first and second dicing lines DLX and DLY or the first and second scribe lane regions 120X and 120Y, the cracks 210C that have been propagated in different directions in the region adjacent to the corner 110E of the chip region 110 may intersect.

The crack sections that have been propagated in different directions in the region adjacent to the corner 110E of the chip region 110 may intersect, and the dicing sections that provide the crack sections may also intersect. Since two crack sections intersect to the outside of the corner 110E of the chip region 110, a part of the corner 110E of the chip region 110 may be a weak portion at which abnormal cracks 210C-A are more likely to be propagated than another part of the substrate 100, Since two crack sections intersect to the outside of the corner 110E of the chip region 110, a part of the corner 110E of the chip region 110 may be a region on which stress is relatively concentrated.

Crack sections or dicing sections may be implemented when the cracks 210C are propagated along the dicing lines DL. However, if an abnormal crack 210C-A occurs in a diagonal direction that intersects the dicing lines DL, for example, in a diagonal direction between the X axis and the Y axis in a part of the corner 110E of the chip region 110, a dicing failure (such as a chipping phenomenon or delamination phenomenon in which a part of the corner 110E of the chip region 110 is detached and separated from the chip region 110 due to the propagation of the abnormal crack 210C-A) may occur. The dicing groove 350 that has been formed before the substrate 100 is diced can prohibit or reduce the occurrence of an abnormal crack 210C-A in a part of the corner 110E of the chip region 110.

While the second crack 210C-2 (not overlapping the dicing groove 350) is propagated while passing through the substrate 100, the first crack 210C-1 that overlaps the dicing groove 350 may have substantially passed fully through the substrate 100. When FIG. 14 and FIG. 15 are compared, the distance D1 in which the first crack 210C-1 passes through the substrate 100 may be shorter than the distance D2 in which the second crack 210C-2 passes through the substrate 100 because the dicing groove 350 has been formed in the distance D1. The concentration of excess stress on a surrounding part of the corner 110E of the chip region 110 can be prohibited or reduced because the dicing groove 350 reduces the distance D1 in which the first crack 210C-1 passes through the substrate 100. Accordingly, in one embodiment of the invention, forming the dicing groove 350 can prohibit or reduce the occurrence of the abnormal crack 210C-A in a surrounding past of the corner 110E of the chip region 110.

Referring to FIG. 17, the substrate 100 may be separated into semiconductor chips 1000 along the dicing lines DL by expanding (indicated by the arrows 800) the substrate 100. A protection film attached to the substrate 100 may be used as an expansion film. The protection film (or the expansion film) may be expanded or pulled in the X axis direction and/or the Y axis direction so that the semiconductor chips 1000 are separated from each other.

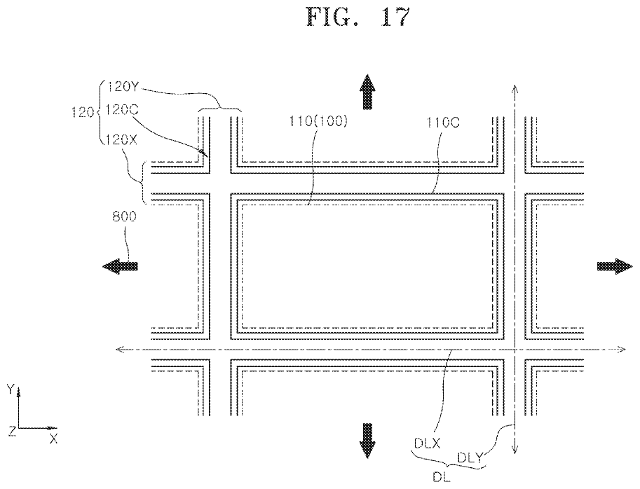

FIG. 18 is a schematic plane view illustrating a step of forming dicing grooves 1350 in a method of manufacturing a semiconductor chip according to one embodiment of the present disclosure. In FIG. 18, the same reference numerals as those in FIGS. 1 to 17 may denote the same members.

Referring to FIG. 18, each of the dicing grooves 1350 that are formed in the active layer 300 of the substrate 100 may be formed to have an oblong shape when viewed from an X-Y plane. When viewed on the X-Y plane, the dicing grooves 1350 may be formed to have the oblong shapes, respectively, so that the ends of the oblong shapes in long axes of the oblong shape are extended to face each other. The oblong shape may have a shape that is relatively elongated in the direction in which the first dicing line DLX is extended. In this case, a distance between the first dicing line DLX and another first dicing line DLX that is adjacent to the first dicing line DLX may be longer than a distance between the second dicing line DLY and another second dicing line DLY that is adjacent to the second dicing line DLY.

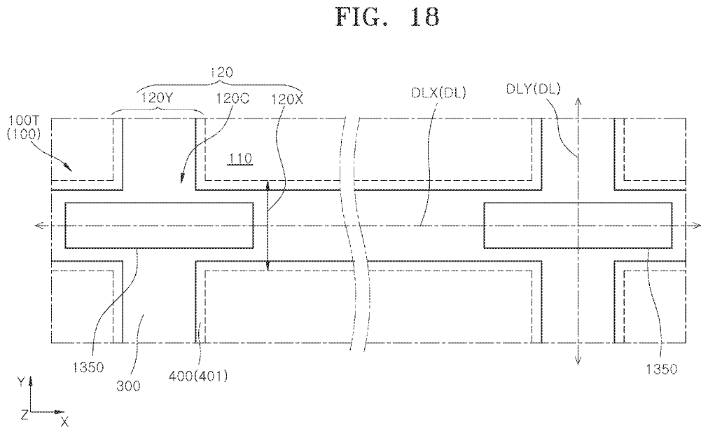

FIG. 19 is a process flowchart illustrating a method of manufacturing a semiconductor chip according to another embodiment of the present disclosure.

Referring to FIG. 19, the method of manufacturing a semiconductor chip according to this embodiment may include an operation S1 of forming a substrate including a semiconductor base, an active layer, and an organic layer, an operation S2 of forming, in the active layer, dicing grooves that are extended to face each other along first dicing lines, an operation S3 of forming modified patterns within the semiconductor base, and an operation S4 of dicing the substrate by propagating cracks.

In the operation S1 of forming a substrate, as presented in FIGS. 2 and 5, the active layer 300 may be formed on the semiconductor base 200. The organic layer 400 may be formed on the active layer 300. In the operation S2 of forming dicing grooves, as presented in FIGS. 6 and 7, the dicing grooves 350 may be formed in a shape in which the dicing grooves 350 are extended to face each other along the first dicing lines DLX from the cross points DLC at which the first and second dicing lines DLX and DLY along which the substrate 100 will be diced intersect. The operation S3 of forming modified patterns within the semiconductor base may include a step of forming the modified patterns 210 so that the modified patterns 210 are aligned along the first dicing line DLX, as presented in FIGS. and 11, The operation S4 of dicing the substrate by propagating cracks may include a step of propagating the crack sections into the semiconductor base 200 and the active layer 300 by generating and propagating the cracks 210C and providing the dicing sections in which the cracks 210C dices the substrate 100, as presented in FIGS. 13, 14, and 15.

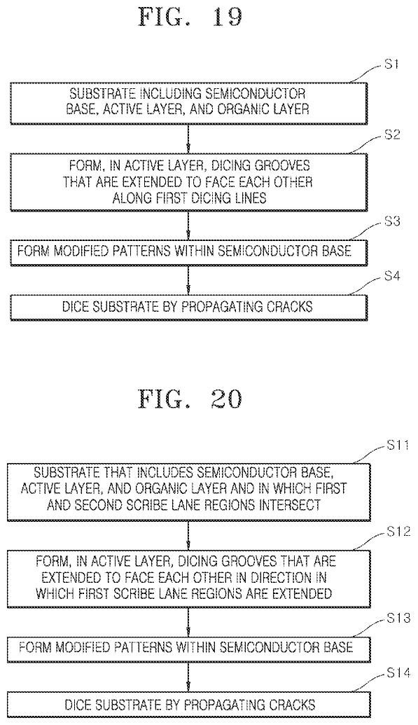

FIG. 20 is a process flowchart illustrating a method of manufacturing a semiconductor chip according to still another embodiment of the present disclosure.

Referring to FIG. 20, the method of manufacturing a semiconductor chip according to this embodiment may include an operation S11 of forming a substrate that includes a semiconductor base, an active layer, and an organic layer and in which first and second scribe lane regions intersect, an operation S12 of forming, in the active layer, dicing grooves that are extended to face each other in the direction in which the first scribe lane regions are extended, an operation S13 of forming modified patterns within the semiconductor base, and an operation S14 of dicing the substrate by propagating cracks.

In the step S11 of forming a substrate, as presented in FIGS. 2 and 5, the active layer 300 may be formed on the semiconductor base 200. The organic layer 400 may be formed on the active layer 300. The first and second scribe lane regions 120X and 120Y may intersect in the substrate 100. In the operation S12 of forming dicing grooves, as presented in FIGS. 6 and 7, the dicing grooves 350 may be formed in a shape in which the dicing grooves 350 are extended to face each other in the direction in which the first scribe lane regions 120X are extended from the cross points 120C at which the first and second scribe lane regions 120X and 120Y of the substrate 100 intersect. The operation S13 of forming modified patterns within the semiconductor base may include a step of forming the modified patterns 210 so that the modified patterns are aligned along the first scribe lane region 120X, as presented in FIGS. 10 and 11. The operation S14 of dicing the substrate by propagating cracks may include a step of propagating the crack sections into the semiconductor base 200 and the active layer 300 by generating and propagating the cracks 210C and providing the dicing sections in which the cracks 210C dice the substrate 100, as presented in FIGS. 13, 14, and 15.

Referring back to FIGS. 13 and 14, the semiconductor device according to another embodiment may include the substrate 100 including the active layer 300 and the organic layer 400 that are formed on the semiconductor base 200. The dicing grooves 350 that are extended to face each other along the first dicing lines DLX from the points DLC at which the first and second dicing lines DLX and DLY in which the substrate 100 will be diced intersect may be formed in the active layer 300. The modified patterns 210 may be aligned in a line along the first and second dicing lines DLX and DLY, and may be formed within the semiconductor base 200 so that some of the modified patterns 210 overlap the dicing grooves 350. The semiconductor device may be diced into the semiconductor chips.

FIG. 21 is a block diagram illustrating an electronic system including a memory card 7800 employing at least one of the semiconductor chips according to the embodiments detailed herein. The memory card 7800 includes a memory 7810 such as a nonvolatile memory device, and a memory controller 7820. The memory 7810 and the memory controller 7820 may store data or read out the stored data. At least one of the memory 7810 and the memory controller 7820 may include at least one of the semiconductor packages according to the embodiments.

The memory 7810 may include a nonvolatile memory device to which the technology of the embodiments of the present disclosure may be applied. The memory controller 7820 may control the memory 7810 such that stored data is read out or data is stored in response to a read/write request from a host 7830,

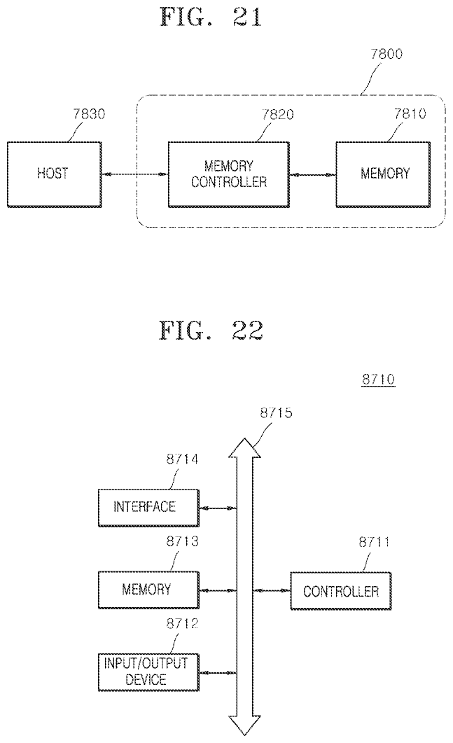

FIG. 22 is a block diagram illustrating an electronic system 8710 including at least one of the semiconductor chips according to the embodiments detailed herein. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include at least one of the semiconductor packages according to the embodiments of the present disclosure. The input/output device 8712 may include at least one selected among a keypad, a keyboard, a display device, a touch screen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution) or WiBro (wireless broadband Internet.

The embodiments of the present disclosure have been described herein, A person having ordinary knowledge in the art to which the present invention pertains will understand that the present invention may be implemented in a modified form without departing from the characteristics of the present disclosure. Accordingly, the disclosed embodiments should be considered from a descriptive viewpoint, not from a limitative viewpoint, One range of the present disclosure is described in the claims. Any differences between the range in the claims and the present disclosure should be construed as being Included in the present disclosure.

What is claimed is:

1. A method of manufacturing a semiconductor chip comprising:
forming a substrate that includes an active layer and an organic layer on a semiconductor base; and
forming dicing grooves by recessing parts of the active layer, the dicing grooves, the dicing grooves being extended to face each other along first dicing lines from points at which the first dicing lines and second dicing lines intersect.

2. The method of claim 1, further comprising:
forming modified patterns within the semiconductor base; and
dicing the substrate into semiconductor chips by propagating cracks into the substrate from the modified patterns.

3. The method of claim 2, wherein some of the modified patterns are formed to overlap the dicing grooves.

4. The method of claim 2, wherein the modified patterns are formed to be aligned along the first and second dicing lines.

5. The method of claim 2, wherein the forming of the modified patterns comprises sequentially radiating a laser light into parts of the semiconductor base at which the modified patterns are to be disposed.

6. The method of claim 1, wherein the dicing grooves are further extended along the second dicing lines and have cross shapes when the dicing grooves are viewed on a plane.

7. The method of claim 1, wherein the dicing grooves are formed to be spaced apart from each other along the first dicing lines.

8. The method of claim 1, wherein the recessing of the parts of the active layer is performed so that remaining portions of the active layer remain between bottoms of the dicing grooves and the semiconductor base.

9. The method of claim 1, wherein the organic layer is formed on the active layer in a shape comprising an opening portion that is extended along the first and second dicing lines so that the dicing grooves and the parts of the active layer disposed between the dicing grooves are exposed.

10. The method of claim 1, wherein:
the organic layer is formed on the active layer in a shape comprising an opening portion that is extended along the first and second dicing lines, and
the recessing of the parts of the active layer comprises:
forming a mask pattern that covers the organic layer and that exposes the parts of the active layer; and
etching the parts of the active layer that are exposed to the mask pattern.

11. A method of manufacturing a semiconductor chip, comprising:
forming a substrate that includes an active layer and an organic layer on a semiconductor base, the substrate further includes first and second scribe lane regions that intersect to partition chip regions; and
forming dicing grooves that are extended to face each other in a direction in which the first scribe lane regions are extended from points at which the first and second scribe lane regions intersect,
wherein the forming of the dicing grooves comprises recessing parts of the active layer.

12. The method of claim 11, wherein:
each of the dicing grooves is formed to be disposed adjacent to corners of the chip region.

13. The method of claim 11, further comprising:
forming modified patterns within the semiconductor base; and
dicing the substrate into semiconductor chips by propagating cracks into the substrate from the modified patterns.

14. The method of claim 13, wherein some of the modified patterns are formed to overlap the dicing grooves.

15. The method of claim 13, wherein the modified patterns are formed to be aligned along the first and second scribe lane regions.

16. The method of claim 13, wherein the forming of the modified patterns comprises sequentially radiating a laser light into parts of the semiconductor base at which the modified patterns are to be disposed.

17. The method of claim 11, wherein the dicing grooves are further extended along the second scribe lane regions and have cross shapes when the dicing grooves are viewed on a plane.

18. The method of claim 11, wherein the dicing grooves are formed to be spaced apart from each other along the first scribe lane regions.

19. The method of claim 1, wherein the recessing of the parts of the active layer is performed so that remaining portions of the active layer remain between bottoms of the dicing grooves and the semiconductor base.

20. The method of claim 11, wherein the organic layer is formed on the active layer in a shape comprising an opening portion that is extended along the first and second scribe lane regions so that the dicing grooves and the parts of the active layer disposed between the dicing grooves are exposed.

21. A semiconductor device comprising:
a substrate comprising an active layer and an organic layer on a semiconductor base,
wherein dicing grooves are formed in the active layer such that the dicing grooves extend to face each other along first dicing lines from points at which the first dicing lines and second dicing lines, along which the substrate is to be diced, intersect.

22. The semiconductor device of claim 21, further comprising modified patterns that are aligned along the first and second dicing lines within the semiconductor base and some of the modified patterns overlap the dicing grooves.

23. A semiconductor device comprising:
a substrate comprising an active layer formed on a semiconductor base;
dicing grooves formed in the active layer; and
stealth dicing patterns formed within the semiconductor base and aligned with the dicing grooves,
wherein the dicing grooves in the active layer extend partially through the active layer.

24. The semiconductor device of claim 23, wherein a thickness of a remaining portion of the active layer underneath the dicing grooves is 20% or less of a thickness of the semiconductor base.

25. The semiconductor device of claim 23, wherein the stealth dicing patterns comprise amorphous silicon or polycrystalline silicon formed within the semiconductor base.
